(19) United States
(12) Patent Application Publication
(10) Pub. No.: US 2023/0178364 A1
(43) Pub. Date: Jun. 8, 2023

(54) REMOVABLE CVD POLYMER FILM FOR SURFACE PROTECTION AND QUEUE PERIOD EXTENSION

(71) Applicant: Lam Research Corporation, Fremont, CA (US)

(72) Inventors: Gregory Blachut, Campbell, CA (US); Diane Hymes, San Jose, CA (US); Stephen M. Sirard, Austin, TX (US)

(21) Appl. No.: 18/003,894

(22) PCT Filed: Jun. 30, 2021
(86) PCT No.: PCT/US2021/040009

§ 371 Date: Dec. 29, 2022

Related U.S. Application Data
(60) Provisional application No. 63/200,326, filed on Mar. 1, 2021.
(60) Provisional application No. 63/047,561, filed on Jul. 2, 2020.

(51) Int. Cl. H01L 21/02; H01L 21/311

(52) U.S. Cl. CPC H01L 21/02118; H01L 21/02271; H01L 21/31127

(57) ABSTRACT

A method includes performing a first substrate treatment on a substrate using a first dry process in a first substrate processing tool operating at vacuum; after the first substrate treatment, depositing a polymer film on an exposed surface of the substrate using a chemical vapor deposition (CVD) process in the first substrate processing tool; removing the substrate from the first substrate processing tool for a queue period; after the queue period, removing the polymer film from the substrate; and performing a second substrate treatment on the substrate using a second dry process in a second substrate processing tool.

### INCORPORATION BY REFERENCE

A PCT request form is filed concurrently with this specification as part of the present application. Each application that the present application claims benefit of or priority to as identified in the concurrently filed PCT request form is incorporated by reference herein in their entireties and for all purposes.

### FIELD

The present disclosure relates to processing of substrates and more particularly to methods for depositing a removable polymer film using a dry process to provide surface protection for substrates between processing steps.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Substrate processing systems perform treatments on substrates such as semiconductor wafers. Examples of substrate treatments include deposition, ashing, etching, cleaning and/or other processes. Process gas mixtures may be supplied to the processing chamber to treat the substrate. Plasma may be used to ignite the gases to enhance chemical reactions.

A significant number of different processes are typically performed on substrates such as semiconductor wafers during fabrication of the substrate. Generally, a single tool does not perform all of the different types of processes that are needed. As a result, the substrate may be processed in one tool or substrate processing station and then the substrate is moved to one or more other tools and/or substrate processing stations until fabrication of the substrate is completed. In some examples, the substrates may be subjected to delay (or queue period) between processes performed by the different tools or substrate processing stations.

During the queue period, the substrates may be exposed to atmospheric conditions during temporary storage or while moving between the separate tools or substrate processing systems. Contamination of exposed surfaces may occur, which may have an adverse effect on one or more downstream processes.

Usually the substrates are moved in a front opening unified pod (FOUP). Some FOUPs include a purge system that maintains an inert gas environment (such as molecular nitrogen (N₂)) to prevent exposure of the substrates to atmospheric conditions and surface contamination. Alternately, the substrates may be processed entirely within a fully integrated vacuum system to prevent surface contamination and to maintain surface integrity. However, both of these strategies are inflexible, capital-intensive, and often ineffective at preventing contamination.

### SUMMARY

A method includes performing a first substrate treatment on a substrate using a first dry process in a first substrate processing tool operating at vacuum; after the first substrate treatment, depositing a polymer film on an exposed surface of the substrate using a chemical vapor deposition (CVD) process in the first substrate processing tool; removing the substrate from the first substrate processing tool for a queue period; after the queue period, removing the polymer film from the substrate; and performing a second substrate treatment on the substrate using a second dry process in a second substrate processing tool.

In other features, the first substrate treatment is performed in a first processing chamber of the first substrate processing tool and depositing the polymer film is performed in a second processing chamber of the first substrate processing tool. The first substrate treatment is performed in a first processing chamber of the first substrate processing tool and depositing the polymer film is performed in the first processing chamber of the first substrate processing tool.

In other features, the second substrate treatment is performed in a first processing chamber of the second substrate processing tool and depositing the polymer film is performed in a second processing chamber of the second substrate processing tool. The second substrate treatment is performed in a first processing chamber of the second substrate processing tool and depositing the polymer film is performed in the first processing chamber of the second substrate processing tool.

In other features, the method includes controlling pressure during the CVD process within a predetermined pressure range. The predetermined pressure range may be between 50 mTorr and 100 Torr, e.g., 50 mTorr and 10 Torr. The substrate comprises a semiconductor substrate. The CVD process comprises an initiated CVD (iCVD) process. The iCVD process uses a plurality of heated filament wires to initiate a reaction.

In other features, the method includes storing the substrate at atmospheric conditions during the queue period. The method includes storing the substrate in a front opening unified pod (FOUP) with inert gas purging during a queue period.

In other features, the method includes removing the polymer film comprises heating the substrate to a temperature in a predetermined temperature range for a predetermined period. The predetermined temperature range is from 80° C. to 600° C., e.g. 80° C. to 400° C. The predetermined period is in a range from 1 second to 5 minutes, e.g., 30 seconds to 5 minutes. The first substrate treatment is selected from a group consisting of etching and deposition. The second substrate treatment is selected from a group consisting of etching and deposition.

In other features, the first substrate treatment is performed in a second processing chamber of the first substrate processing tool and then transferred through a vacuum transfer module to the first processing chamber of the first substrate processing tool. The polymer film includes a polymer backbone with alternating carbon-oxygen bonds.

In other features, the polymer film may be selected from a group consisting of polyoxymethylene, polyacetaldehyde, polypropionaldehyde, polybutyraldehyde, polyvaleraldehyde, polyheptaldehyde, polyoctanaldehyde, polynonanaldehyde, and polydecaldehyde. The polymer film may be a copolymer comprising a homopolymer selected from a group consisting of polyoxymethylene, polyacetaldehyde, polypropionaldehyde, polybutyraldehyde, polyvaleraldehyde, polyheptaldehyde, polyoctanaldehyde, polynonanaldehyde, and polydecaldehyde. In some embodiments, the copolymer may consist of homopolymers selected from a group consisting of polyoxymethylene, polyacetaldehyde, polypropionaldehyde, polybutyraldehyde, polyvaleraldehyde, polyheptaldehyde, polyoctanaldehyde, polynonanaldehyde, and polydecaldehyde.

In other features, during deposition of the of the polymer film, the method includes delivering precursor selected from a group consisting of monomeric aldehyde and a precursor with alternating carbon-oxygen ring structures. The precursor is selected from a group consisting of 1,3,5-trioxane and paraldehyde. The monomeric aldehyde is selected from a group consisting of formaldehyde, ethanal, propanal, butanal, pentanal, hexanal, heptanal, octananal, nonanal, or decanal, or any non-linear branched version of these molecules.

The polymer film has a thickness in a range from 10 nm to 5000 nm. The polymer film has a thickness in a range from 50 nm to 5000 nm. The polymer film has a thickness in a range from 100 nm to 1000 nm.

In other features, the method includes performing post processing on the polymer film. The post processing is selected from a group consisting of exposure to solvent, annealing and a soft bake. The method includes removing the polymer film comprises exposing the polymer film to radiation. The method includes controlling a temperature of a substrate support during deposition of the polymer film to a temperature that is less than other surfaces in a processing chamber where the deposition of the polymer film occurs.

In other features, the method includes depositing a cap layer on the polymer film. The cap layer is deposited by a CVD process. The cap layer is deposited in the first substrate processing tool. The cap layer may be an inorganic layer, e.g., SiOx, SnOx, AlOx, TiOx, ZrOx, HfOx, ZnOx, and SiNx wherein x is a number greater than 0. The cap layer may be a polymer layer. In other features, the method further includes incorporating a weak organic acid in the polymer film.

A method includes performing a first substrate treatment on a substrate using a first dry process in a first substrate processing tool operating at vacuum; after the first substrate treatment, depositing a polymer film on an exposed surface of the substrate using a chemical vapor deposition (CVD) process in the first substrate processing tool; removing the substrate from the first substrate processing tool for a queue period, wherein the polymer film is selected from a group consisting of polyoxymethylene, polyacetaldehyde, polypropionaldehyde, polybutyraldehyde, polyvaleraldehyde, polyheptaldehyde, polyoctanaldehyde, polynonanaldehyde, and polydecaldehyde.

In other features, the method includes depositing a cap layer on the polymer film. The cap layer is deposited by a CVD process. The cap layer is deposited in the first substrate processing tool. The cap layer may be an inorganic layer, e.g., SiOx, SnOx, AlOx, TiOx, ZrOx, HfOx, ZnOx, and SiNx wherein x is a number greater than 0. The cap layer may be a polymer layer. In other features, the method further includes incorporating a weak organic acid in the polymer film.

A method includes performing a first substrate treatment on a substrate using a first dry process in a first substrate processing tool operating at vacuum; after the first substrate treatment, depositing a polymer film on an exposed surface of the substrate using a chemical vapor deposition (CVD) process in the first substrate processing tool; removing the substrate from the first substrate processing tool for a queue period, wherein the polymer film is a copolymer comprising one or more homopolymers selected from a group consisting of polyoxymethylene, polyacetaldehyde, polypropionaldehyde, polybutyraldehyde, polyvaleraldehyde, polyheptaldehyde polyoctanaldehyde, polynonanaldehyde, and polydecaldehyde. In some embodiments, the copolymer may consist of homopolymers selected from a group consisting of polyoxymethylene, polyacetaldehyde, polypropionaldehyde, polybutyraldehyde, polyvaleraldehyde, polyheptaldehyde, polyoctanaldehyde, polynonanaldehyde, and polydecaldehyde.

In other features, the method includes depositing a cap layer on the polymer film. The cap layer is deposited by a CVD process. The cap layer is deposited in the first substrate processing tool. The cap layer may be an inorganic layer, e.g., SiOx, SnOx, AlOx, TiOx, ZrOx, HfOx, ZnOx, and SiNx wherein x is a number greater than 0. The cap layer may be a polymer layer. In other features, the method further includes incorporating a weak organic acid in the polymer film.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a substrate processing system for depositing a polymer film onto an exposed surface of a substrate using chemical vapor deposition (CVD) according to the present disclosure;

FIG. 2A and 2B are methods for depositing and removing the polymer film on a substrate, respectively, using CVD according to the present disclosure;

FIG. 3 is a functional block diagram of another example of a substrate processing system for depositing polymer film on a substrate using initiated CVD (iCVD) according to the present disclosure;

FIG. 4 is a plan view illustrating heated wire filaments that are used in FIG. 3 to initiate reactions according to the present disclosure;

FIGS. 5A and 5B are flowcharts of methods for applying and removing the polymer film using iCVD according to the present disclosure;

FIG. 6 is a functional block diagram of an example of a substrate processing tool including a plurality of substrate processing stations according to the present disclosure; and

FIG. 7 is a functional block diagram of an example of a fab room including a plurality of substrate processing tools according to the present disclosure.

FIG. 8 shows a schematic example of a substrate including a surface protected with a multi-layer protection stack including a polymer film and a cap layer.

In the drawings, reference numbers may be reused to identify similar and/or identical elements.

### DETAILED DESCRIPTION

To alleviate some of the foregoing problems, systems and methods according to the present disclosure deposit a polymer film on an external surface of a substrate using a dry process to protect the substrate during the queue period. The polymer film can be readily removed after the queue period prior to downstream processing. In some examples, the removal is performed by heating at a temperature below 400° C. with little or no residue.

Use of the polymer film alleviates problems associated with surface contamination of the substrate during the queue period between processes or when the substrate is moved between substrate processing systems used during fabrication. In other words, after processing the substrate in one tool or substrate processing system, the substrate is coated with a polymer film using a dry CVD or iCVD process. The polymer film prevents exposure of an outer surface of the substrate to atmospheric conditions when the substrate is not in a vacuum environment.

Polymer film including polyaldehyde polymers (such as poly(phthalaldehyde) and related copolymers) has been deposited using wet processes to prevent contamination of the substrate surface due to exposure to ambient conditions. Substrate treatments such as etching, deposition or cleaning normally involves dry processes performed in a vacuum environment. Since the polymer film described above is applied using a wet process, the substrate needs to be removed from the vacuum environment of the preceding dry process and moved to a wet processing system where the polymer film is applied. Therefore, the substrate is exposed to atmospheric conditions prior to application of the polymer film, which is problematic. Wet processing may also cause a variety of downstream processing issues. For example, wet processing may cause problems such as pattern collapse for high aspect ratio (HAR) features of the substrate. HAR features as described herein refer to features having a depth to width ratio greater than 4:1.

Systems and methods according to the present disclosure relate to a dry CVD or iCVD process for depositing a polymer film on a substrate to protect the substrate from surface contamination during the queue period. The dry film deposition process can be integrated into a vacuum tool with improvements in contamination reduction and reduced cost since the wet processing tools are no longer required.

After the preceding process step (such as deposition, cleaning, or etching), the substrate is brought to vacuum in the same or different chamber as the preceding process step. In some examples, the predetermined pressure during deposition of the polymer film is in a range from 50 mTorr to 100 Torr, or 50 mTorr to 10 Torr, although other process pressures can be used. One or more precursor gases for the polymer film are supplied to the processing chamber. In some examples, two or more different precursors are used to make a copolymer film. A copolymer may be a random or block copolymer. In addition, initiators and/or catalysts can also be supplied, typically through a second plenum.

Using a substrate processing system that performs CVD or iCVD, a polymer film is deposited onto a substrate to protect the exposed surface of the substrate from modification by oxygen, water, halogens, or other reactive species to minimize variability associated with the queue period in between process steps. The polymer film is removed prior to a downstream process. In some examples, the polymer film is removed by heating the substrate under vacuum to a temperature greater than or equal to 80° C. and less than or equal to 600° C., or less than equal to 400° C.

In some examples, the polymer film includes polyaldehydes (sometimes called polyacetals), where the polymer backbone includes alternating carbon-oxygen bonds. These polymer films have a low ceiling temperature and will readily revert back to a monomeric form when exposed to a sufficiently high temperature.

Examples of these types of polymer film include polyoxymethylene and polyacetaldehyde that are deposited using a dry CVD or iCVD process. In some examples, the precursors for the polymer film include monomeric aldehyde or a precursor with alternating carbon-oxygen ring structures such as 1,3,5-trioxane or paraldehyde. Examples of monomeric aldehydes include formaldehyde, ethanal, propanal, butanal, pentanal, hexanal, heptanal, octananal, nonanal, or decanal, and any non-linear (branched) versions of these molecules.

Other examples of polymer films include polypropionaldehyde, polybutyraldehyde, polyvaleraldehyde, and polyheptaldehyde, and copolymers of these aforementioned homopolymers, for example polyoxymethylene-r-polyacetaldehyde.

In some examples, the precursors are combined over the substrate. For example, an energy source such as a heated wire filament or a hot surface are used to activate one or more of the precursors. In some examples, the substrate is cooled below a temperature of other surfaces in the processing chamber to promote adsorption of the precursors, or condensation of the polymer film, onto the substrate. In other examples, the substrate is heated to a predetermined temperature to promote the polymerization reaction.

The process is continued for a predetermined period until a predetermined thickness of the polymer film grows and then the reaction is stopped. In some examples, the predetermined thickness is in a range from 10 nm to 5000 nm. In some examples, the predetermined thickness is in a range from 50 nm to 5000 nm. In other examples, the predetermined thickness is in a range from 100 nm to 1000 nm.

In some embodiments, the polymer film includes an organic weak acid. Organic weak acids are organic acids having a pKa≥1, with examples including tartaric acid and oxalic acid. Examples include linear alkyl carboxylic acids, CxH₂ₓO₂, where X is an integer, and the corresponding dicarboxylic acid variants. Particular examples include including methanoic acid (X=1) and acetic acid (X=2). Particular examples of dicarboxylic acids include ethanedioic acid and propanedioic acid. The organic weak acid may also be variants of any of these with additional alcohol substitutions and/or unsaturated bonds. For example, oxoethanoic acid, 2-hydroxyethanoic acid, prop-2-enoic acid, 2-propynoic acid, 2-hydroxypropanedioic acid, oxopropanedioic acid, 2,2-dihydroxypropanedioic acid, 2-oxopropanoic acid, 2-hydroxypropanoic acid, 3-hydroxypropanoic acid, 2,3-dihydroxypropanoic acid, etc. may be used.

The organic weak acid may be deposited at the same time as the polymer of the polymer film in some embodiments by flowing the weak acid alongside the other precursors. In other embodiments, it may be added to the polymer film after deposition, where the polymer film is exposed to the vapor of the organic weak acid, and the organic weak acid diffuses into the film to some extent. In some embodiments, a portion of the polymer film may be deposited followed incorporation or other deposition of the organic weak acid, with subsequent portions of the polymer film deposited in the same manner. In some examples, the organic weak acid incorporation in the polymer film is in a range from 0.001 to 10 percent by weight. In some examples, the organic weak acid incorporation in the polymer film is in a range from 0.01 to 1 percent by weight.

Polymer films that include an organic weak acid as described above are stable at room temperature but may exhibit accelerated degradation characteristics compared to the neat polymer film formulated without the organic weak acid.

Post processing may be performed on the substrate after the polymer film is deposited. In some examples, the post processing includes exposure to solvent, annealing and/or a soft-bake. The post processing can be performed in the same processing chamber where the film was grown or the substrate can be moved to another processing chamber. For example, annealing may be used to improve film uniformity, to fill in topography (especially high-aspect-ratio features), to drive out unreacted precursors or other volatiles, to remove voids, and/or to improve film properties. Thermal annealing takes place at a temperature lower than that of the degradation temperature and may be less than or equal to 250° C.

In some embodiments, one or more cap layers are deposited after the polymer film is deposited. Like the polymer film, the one or more cap layers can be vapor deposited in some embodiments. Forming a cap layer is discussed further below.

After processing of the polymer film is complete, the substrate can be exposed to atmospheric conditions during the queue period without contamination. The polymer film is effective in protecting the exposed surface of the substrate for typical queue periods. For example, a typical queue period is less than or equal to 24 hours (before subsequent processing is performed). In other examples, the typical queue period is less than or equal to 4 hours. However, longer or shorter queue periods can be used.

Before the subsequent or downstream processing begins, the polymer film is removed. In some examples, the substrate is heated in a chamber for a predetermined period at a predetermined temperature to strip the polymer film. In some examples, the predetermined temperature is in a range from 80° C. to 400° C., although other temperatures can be used, including up to and including 600° C. In some examples, the predetermined period is in a range from 30 seconds to 5 minutes, although longer or shorter durations can be used. In some embodiments, the predetermined period is in a range of 1 second to 5 minutes, e.g., 1 to 30 seconds.

In some examples, the substrate is exposed to electromagnetic radiation at one or more wavelengths to promote degradation of the polymer film or degradation of the trace organic char contamination that may form as the degradation takes place. In some examples, the electromagnetic radiation is primarily in the ultraviolet or vacuum ultraviolet wavelength range. The radiation may be broadband or monochromatic. Once the polymer film is removed, the substrate is moved to the next tool or substrate processing system. In some examples, the polymer film is stripped in a rapid thermal processing (RTP) chamber to allow precise control over the heating rate of the substrate. In RTP chamber, a multi-setpoint temperature profile may be employed to optimize film removal. Target temperatures range from 80° C. to 600° C., e.g., 80° C. to 400° C., and dwell times range from 1 seconds to 5 minutes, e.g., 30 seconds to 5 minutes. The rate of heating or cooling in the rapid thermal annealer range from 1° C./minute to 200° C./second.

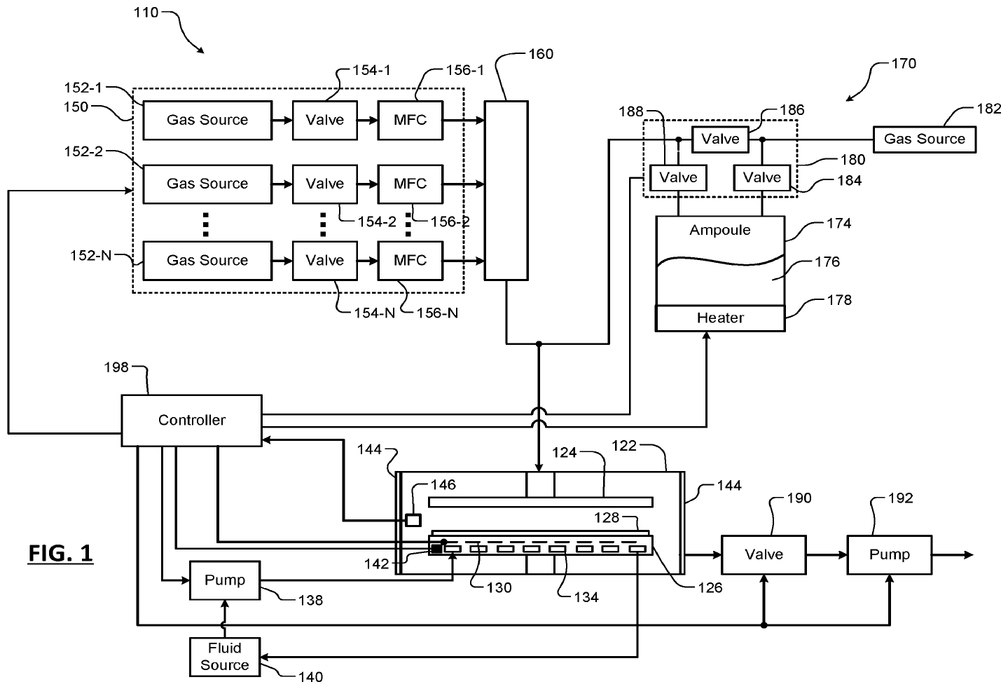

Referring now to FIG. 1, an example of a substrate processing system 110 for depositing the polymer film onto a substrate is shown. The substrate processing system 110 includes a processing chamber 122 that encloses other components of the substrate processing system 110. The substrate processing system 110 includes a gas distribution device 124 such as a showerhead that introduces and distributes process gases. Alternately, the process gases may be introduced in another manner. A substrate support 126 may be arranged below the gas distribution device 124. In some examples, the substrate support 126 includes a pedestal or an electrostatic chuck (ESC).

In some examples, the substrate support 126 is temperature controlled. In some examples, a temperature of the substrate support is used to help initiate polymer CVD. For example, the substrate support 126 may include resistive heaters 30 and/or cooling channels 134. The cooling channels 134 may be supplied by fluid delivered using a pump 138 and a fluid source 140. One or more sensors 142 may be used to monitor a temperature of the substrate support 126. The one or more sensors 142 may include thermocouples that are located in the substrate support 126, or in fluid conduits connected to the substrate support 126. Alternately, other types of sensors such as thermal or infrared sensors located in the processing chamber 122 (remotely from the substrate support) can be used to monitor the temperature of the substrate or substrate support.

Surfaces of the processing chamber 122 can be heated by heaters 144. While the sidewalls of the processing chamber 122 are heated in FIG. 1, other surfaces of the processing chamber 122 such as the top surface, the bottom surface and the gas distribution device can also be heated. In some examples, the surfaces of the processing chamber are heated to a temperature that is greater than a temperature of the substrate. One or more sensors 146 may be used to monitor chamber operating parameters such as temperature and/or pressure.

The substrate processing system 110 further includes a gas delivery system 150 with one or more gas sources 152-1, 152-2, . . . , and 152-N (collectively gas sources 152), where N is an integer greater than zero. The gas sources supply one or more gases to the processing chamber 122. The gas sources 152 are connected by valves 154-1, 154-2, . . . , and 154-N (collectively valves 154) and mass flow controllers (MFCs) 156-1, 156-2, . . . , and 156-N (collectively mass flow controllers 156) to a manifold 160. An output of the manifold 160 is fed to the processing chamber 122. For example only, the output of the manifold 160 is fed to the gas distribution device 124.

A vapor delivery system 170 may be used to deliver vaporized precursor to the processing chamber 122. The vapor delivery system 170 includes an ampoule 174 that stores liquid precursor 176. A heater 178 may be used to heat the liquid precursor as needed to increase vaporization. Pressure in the ampoule 174 may also be controlled to a predetermined pressure. Due to the monomer's instability when heated, the monomer may be kept at room temperature or even cooled, and a small portion that is delivered to a vaporizing device may be heated at point of vaporization.

A valve system 180 may be used to control the supply of carrier or push gas from a gas source 182 and/or supply of the vaporized precursor. For example, the valve system 180 may include valves 184, 186 and 188. In this example, an inlet of the valve 184 is connected between the gas source 182 and an inlet of the valve 186. An outlet of the valve 184 is connected to an inlet of the ampoule 174. An outlet of the ampoule 174 is connected to an inlet of the valve 188. An outlet of the valve 188 is connected to an output of the valve 186 and to an inlet of the gas distribution device 124. The valve system 180 may be configured to supply no gas, carrier gas and/or carrier gas and vaporized precursor. A valve 190 and pump 192 may be used to control pressure in the processing chamber 122 and/or to evacuate reactants from the processing chamber 122.

A controller 198 may be used to control various components of the substrate processing system 110. For example only, the controller 198 may be used to control flow of process, carrier and precursor gases, vaporized precursor, water vapor, ammonia vapor, removal of reactants, monitoring of chamber parameters, etc.

In some examples, the substrate processing system 110 may be used to perform a dry process treatment such as depositing, etching or cleaning on the substrate prior to depositing the polymer layer on the substrate using the substrate processing system 110. In other examples, the treatment is performed on the substrate in another chamber before being delivered to the substrate processing system 110 for deposition of the polymer film.

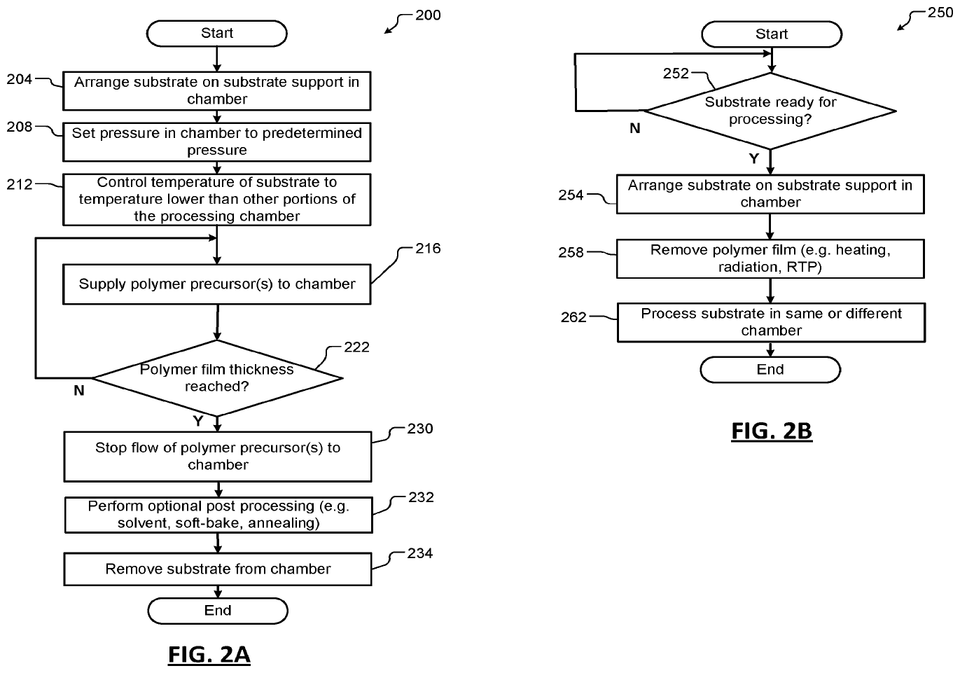

Referring now to FIGS. 2A and 2B, a method 200 for depositing a polymer film on a substrate is shown. At 204 in FIG. 2A, the substrate is arranged on a substrate support in a chamber. At 208, the pressure in the chamber is set in a predetermined pressure range. At 212, the temperature of the substrate is controlled to a predetermined temperature range. In some examples, the temperature of the substrate is controlled to a temperature that is less than other surfaces in the chamber. At 216, a polymer precursor gas mixture is delivered to the chamber. When a predetermined polymer film thickness is reached as determined at 222, the polymer precursor gas mixture is stopped at 230. At 232, optional post-processing is performed.

In some examples, the post processing includes exposure to solvent, annealing and/or a soft-bake. The post processing can be performed in the same processing chamber where the film was grown or the substrate can be moved to another processing chamber. For example, annealing may be used to improve film uniformity, to fill in topography (especially high-aspect-ratio features), to drive out unreacted precursors or other volatiles, to remove voids, or to improve film properties. At 234, the substrate is removed from the chamber.

As discussed further below, in some embodiments, one or more cap layers are deposited. They may be deposited by CVD in some embodiments after operation 230 prior to operation 234. In such embodiments, the one or more cap layers may be deposited before or after operation 232, or as part of operation 232. In other embodiments, one or more cap layers may be deposited in a different chamber after operation 234.

In FIG. 2B, a method 250 for removing the polymer film is performed at the end of the queue period and prior to further processing. When the substrate is ready for processing at 252, the substrate is arranged on the substrate support in a chamber.

At 258, the polymer film is removed. The substrate is heated in a chamber for a predetermined period at a predetermined temperature in a predetermined temperature range to strip the polymer film. In some examples, the predetermined temperature range is from 80° C. to 400° C., although other temperatures can be used. For example, polyaldehydes decompose in this temperature range. In some examples, the predetermined period is in a range from 30 seconds to 5 minutes, although longer or shorter durations can be used.

In some examples, the substrate is exposed to electromagnetic radiation at one or more wavelengths to promote degradation of the polymer film or degradation of the trace organic char contamination that may form as the degradation takes place. Once the polymer film is removed, the substrate is processed in the same chamber of moved to the next tool or substrate processing chamber. In some examples, the polymer film is stripped in a rapid thermal processing (RTP) chamber to allow control over rate of heating rate of the substrate. At 262, further processing of the substrate is performed in the same chamber or a different chamber.

Removal of a cap layer, if present, is discussed further below.

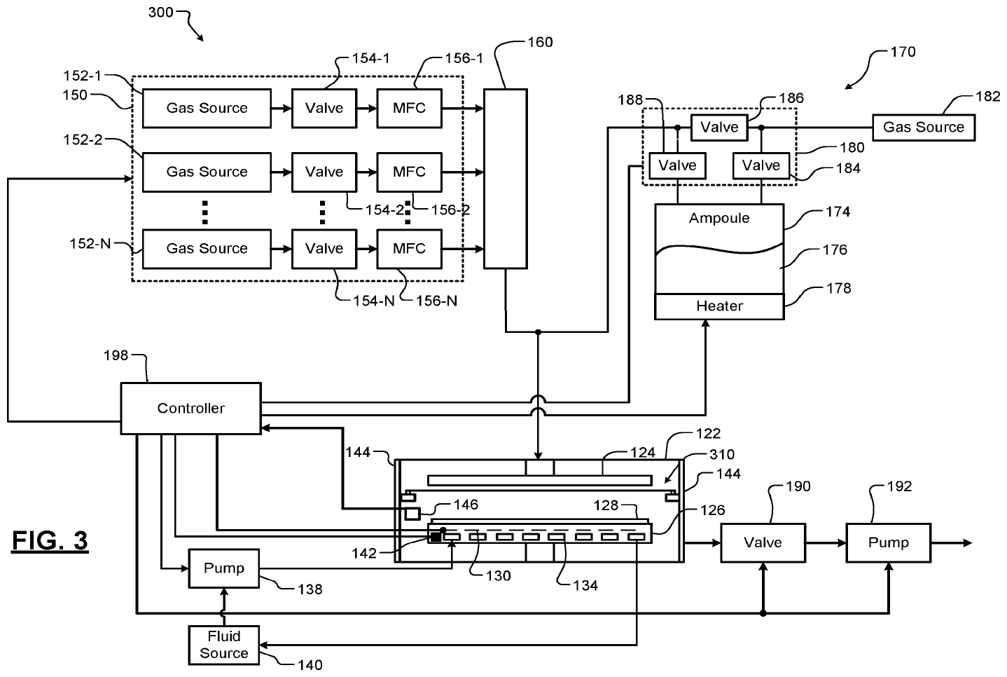

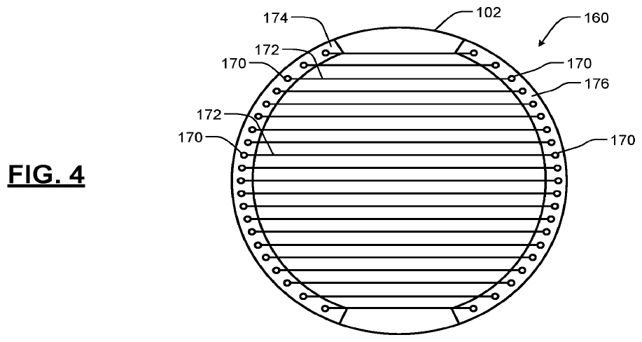

Referring now to FIGS. 3-4, a substrate processing system 300 for performing initiated chemical vapor deposition (iCVD) is shown. The substrate processing system 300 is similar to the substrate processing system 110 described above. However, the substrate processing system 300 further includes a plurality of heated filament wires generally identified at 310 in FIG. 3. Heat produced by the heated filament wires 310 is used to initiate reactions. In FIG. 4, an example of the plurality of heated filament wires 310 is shown to include conductor pairs 410 that are connected to heated filament wires 412. In this example, the conductor pairs 410 are attached to a first support and a second support 414, 416 that are arranged in the processing chamber 122 (e.g. attached to sidewalls of the processing chamber 122).

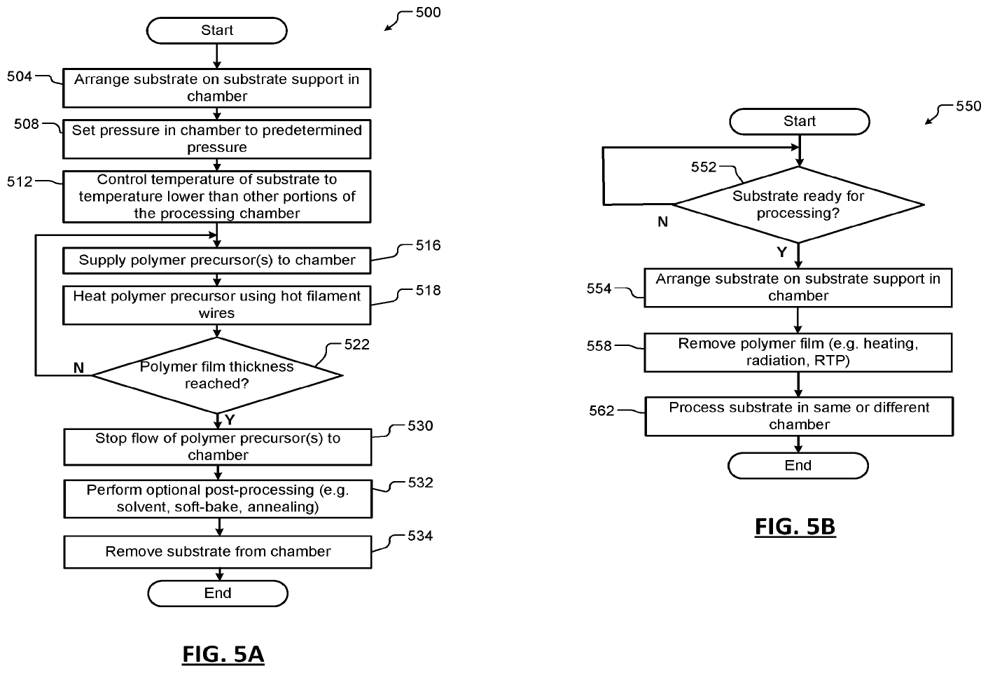

Referring now to FIGS. 5A and 5B, a method 500 for depositing a polymer film on a substrate is shown. At 504 in FIG. 5A, the substrate is arranged on a substrate support in a chamber. At 508, the pressure in the chamber is set in a predetermined pressure range. At 512, the temperature of the substrate is controlled to a predetermined temperature range. In some examples, the temperature of the substrate is controlled to a temperature less than other surfaces in the chamber. At 516, a polymer precursor gas mixture is delivered to the chamber. When a predetermined polymer film thickness is reached as determined at 522, the polymer precursor gas mixture is stopped at 530. At 532, post processing may be performed as previously described above. At 534, the substrate is removed from the chamber.

As discussed further below, in some embodiments, one or more cap layers are deposited. They may be deposited by CVD in some embodiments after operation 530 and prior to operation 534. In such embodiments, the one or more cap layers may be deposited before or after operation 532, or as part of operation 532. In other embodiments, one or more cap layers may be deposited in a different chamber after operation 234.

In FIG. 5B, a method 550 for removing the polymer film is performed at the end of the queue period and prior to further processing. When the substrate is ready for processing at 552, the substrate is arranged on the substrate support in a chamber. At 558, the polymer film is removed as previously described above. At 562, further processing of the substrate is performed in the same chamber or a different chamber. Removal of a cap layer, if present, is discussed further below.

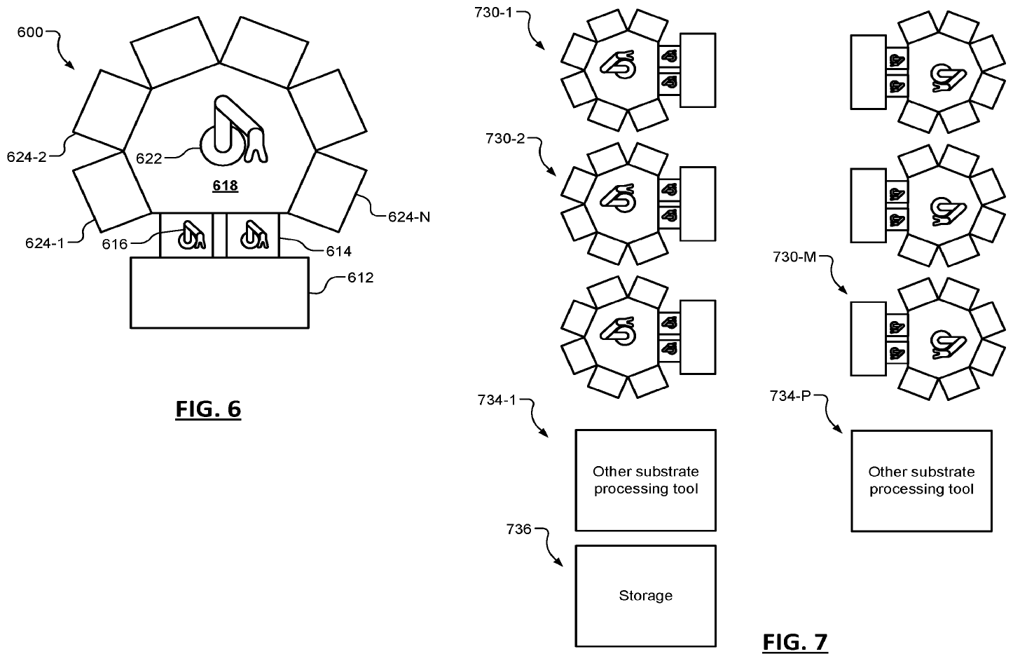

Referring now to FIG. 6, an example of a tool 600 according to the present disclosure is shown. The tool 600 includes processing chambers 624-1, 624-2, . . . , and 624-N, where N is an integer greater than 1. Substrates may be delivered in a FOUP to a loading/unloading station 612. Robots 614, 616 in load locks 617, 619, respectively, deliver the substrate from the FOUP to a vacuum transfer module 618 including a robot 622. The robot 622 delivers the substrate to one or more of the processing chambers 624-1, 624-2, . . . , and 624-N for dry processing, polymer film removal and/or polymer film deposition.

For example, a substrate including a polymer film that was previously deposited is delivered after the queue period from storage or another location to the processing chamber 624-1 for further processing. In the processing chamber 624-1, the polymer film is removed as described herein. Afterwards, the robot 622 moves the substrate to one or more of the processing chambers and substrate treatment such as deposition, etching or cleaning is performed. Alternately, the substrate remains in same processing chamber (e.g. 624-1) that removed the polymer film and the substrate treatment such as deposition or etching is performed in the same chamber.

The robot moves the substrate to another one of the processing chambers (e.g. 624-3) and the polymer film is deposited again. Alternately, the robot remains in same processing chamber (e.g. 624-1 or 624-2) and the polymer film is deposited in the same chamber. Thereafter, the substrate is removed from the tool 600 and processed in another tool after the queue period.

Referring now to FIG. 7, a fab facility includes a plurality of tools 730-1, 730-2, . . . , and 730-M, where M is an integer greater than one. The fab facility further includes other substrate processing chambers or tools 734-1, 734-2 . . . , and 734-P and storage 736. A substrate may be processed by one of the tools 730-1 and then a processing chamber of the tool 730-1 deposits a polymer layer. The substrate may be moved to the storage 736 or another location for during the queue period until the next process can be performed. In some examples, a FOUP or a FOUP with inert purging may be used to move the substrates and/or to store the substrates during the queue period.

After the queue period, the substrate is moved to another one of the tools 734-1, 734-2 . . . , and 734-P, the polymer film is removed and further processing is performed. In some examples, after the further processing is performed, the polymer film is added prior to another queue period and the process may be repeated as needed.

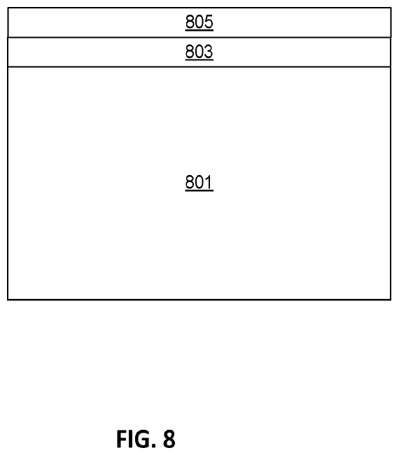

In some embodiments, a cap layer may be deposited on the polymer film. FIG. 8 shows an example of a substrate 801 including a surface to be protected. A multi-layer film including polymer film 803 and cap layer 805 is on the substrate surface and serves as a transient protective layer. The polymer film 803 may be a vapor deposited film as described above with respect to FIGS. 2A and 5A.

In addition to the polymer film, the multi-layer film includes one or more cap layers that provide protection from unwanted oxidation, corrosion, or halogenation due to exposure to ambient conditions. In the example of FIG. 2A, the cap layer may be formed before, after, or as part of operation 232 or after operation 234. Similarly, in the example of FIG. 5A, the cap layer may be formed before, after, or as part of operation 532 or after operation 534.

In the example of FIG. 8, there is one cap layer 805, however additional cap layers of the same or different composition may be used. Examples of thicknesses may range from 2-1000 nm for a polymer film 803, and from a few nm's to several microns for the one or more cap layers. Thicknesses may depend on storage ambient and length of time, for example.

The cap layer 805 is a solid, non-aqueous film and may be a high-density material with little-to-no porosity or defects. The cap layer may be characterized as having greater moisture or oxygen barrier properties than the polymer film. It is deposited in a manner that does not degrade the polymer film. In some embodiments, this involves thermal (non-plasma) deposition at temperatures less than 150° C. (or other temperature at which the polymer film degrades). In some embodiments, there is no direct exposure of the polymer film to a plasma. Example deposition processes can include electron-beam evaporation, various sputtering processes, atomic layer deposition, and chemical vapor deposition. Example cap layers can include oxide films such as silicon oxides (SiOₓ), tix oxides (SnOₓ), aluminum oxides (AlOₓ), titanium oxides (TiOₓ), zirconium oxides (ZrOₓ), hafnium oxides (HfOₓ) and zinc oxides (ZnOₓ) and nitride films such as silicon nitrides (SiNₓ) wherein x is a number greater than 0.

In some embodiments, the cap layer may also be a polymer. These are referred to as polymer cap layers to distinguish the polymer film 803. Polymer cap layers can be vapor deposited (by chemical vapor deposition or physical vapor deposition). Other cap layers that may be vapor deposited include polymer-like films, resin films, and organic molecules. In some embodiments, polymers can be grown in-situ from precursors delivered in the vapor phase.

Examples of cap layers that can be deposited by vapor deposition or solution-based deposition include polytetrafluoroethylene (PTFE), polyethylene (PE), polyacrylates (including derivatives, substituted forms, and copolymers thereof), polystyrene (including derivatives, substituted forms, and copolymers thereof), polyimides, polyamides, polyesters, polyurea, polyaldehydes, and polyurethanes.

The polymer film 803 generally has a backbone with alternating carbon-oxygen bonds as described above and can be removed in a benign way (e.g., exposure to UV and/or bake at 150° C.-300° C.) with little residue left behind. To construct the multi-layer film, a polymer film of a polymer including a polymer backbone having alternating carbon-oxygen bonds is deposited by CVD as described above. Then one or more cap layers are subsequently deposited onto the polymer film. Vapor-phase, low temperature, non-plasma CVD techniques may be used to avoid degradation of the polymer film. For example, CVD deposition at a temperature of no more than or less than 150° C. may be used without radiation. Multiple different types of films may be deposited multiple times in a repeated stack to optimize protection of the surface.

In some embodiments, a first cap layer may be deposited by a mild CVD process to protect the underlying polymer film followed by deposition by a harsher technique such as PECVD to grow faster, more robust films. In some embodiments, the mild CVD process may be performed in the same chamber as the polymer film deposition with the harsher process performed in the same or a different chamber. The temperature of the substrate should generally below 150° C. (or other degradation temperature) of the underlying polymer film throughout the entire process or exceed it for no more than a few seconds.

In some embodiments, one or more cap layers are deposited on the polymer film in the same processing chamber (e.g., processing chamber 122 in FIG. 1 or FIG. 3). In some embodiments, a multi-station chamber may be used to deposit a polymer film such as polymer film 803 in a first station or set of stations and a cap layer in a second station or set of stations.

When ready for further processing of the substrate, the one or more cap layers are removed. This can be a single operation or multiple operations. Further, the one or more cap layers and the polymer film can be removed in the same or different operations.

In some embodiments, removing the one or more cap layers can involve using a plasma or solvent to degrade these layers, turning off the plasma or removing the solvent before the underlying polymer film itself is fully removed. The surface can then be baked under vacuum or at ambient to drive off the polymer film, leaving behind the clean surface of interest, which was protected from the harsh chemistries or conditions used to remove the cap layers.

In some embodiments, the one or more cap layers may be peeled-off by attaching them with an adhesive to another substrate, while the first substrate remains chucked or affixed to some kind of holder. The whole assembly is then heated while being pulled apart. Since the heating may serve to degrade the polymer film, this substrate-polymer film interface is where the two halves separate, leaving behind a clean substrate free of the protecting film, while the bulk of the protecting film remains attached by the adhesive to the second substrate. Similarly, in some embodiments, the polymer film can be degraded to make it easy to remove, with gravity or other force used to separate the polymer film and the overlaying cap layer(s).

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A method comprising:
performing a first substrate treatment on a substrate using a first dry process in a first substrate processing tool operating at vacuum;
after the first substrate treatment, depositing a polymer film on an exposed surface of the substrate using a chemical vapor deposition (CVD) process in the first substrate processing tool;
removing the substrate from the first substrate processing tool for a queue period;
after the queue period, removing the polymer film from the substrate; and
performing a second substrate treatment on the substrate using a second dry process in a second substrate processing tool.

2. The method of claim 1, wherein the first substrate treatment is performed in a first processing chamber of the first substrate processing tool and depositing the polymer film is performed in a second processing chamber of the first substrate processing tool.

3. The method of claim 1, wherein the first substrate treatment is performed in a first processing chamber of the first substrate processing tool and depositing the polymer film is performed in the first processing chamber of the first substrate processing tool.

4. The method of claim 1, wherein the second substrate treatment is performed in a first processing chamber of the second substrate processing tool and depositing the polymer film is performed in a second processing chamber of the second substrate processing tool.

5. The method of claim 1, wherein the second substrate treatment is performed in a first processing chamber of the second substrate processing tool and depositing the polymer film is performed in the first processing chamber of the second substrate processing tool.

6. The method of claim 1, further comprising controlling pressure during the CVD process within a predetermined pressure range.

7. The method of claim 6, wherein the predetermined pressure range is between 50 mTorr and 100 Torr.

8. The method of claim 1, wherein the substrate comprises a semiconductor substrate.

9. The method of claim 1, wherein the CVD process comprises an initiated CVD (iCVD) process.

10. The method of claim 9, wherein the iCVD process uses a plurality of heated filament wires to initiate a reaction.

11. The method of claim 1, further comprising storing the substrate at atmospheric conditions during the queue period.

12. The method of claim 1, further comprising storing the substrate in a front opening unified pod (FOUP) with inert gas purging during a queue period.

13. The method of claim 1, wherein removing the polymer film comprises heating the substrate to a temperature in a predetermined temperature range for a predetermined period.

14. The method of claim 13, wherein the predetermined temperature range is from 80° C. to 600° C.

15. The method of claim 13, wherein the predetermined period is in a range from 1 second to 5 minutes.

16. The method of claim 13, wherein the first substrate treatment is selected from a group consisting of etching and deposition.

17. The method of claim 13, wherein the second substrate treatment is selected from a group consisting of etching and deposition.

18. The method of claim 2, wherein the first substrate treatment is performed in a second processing chamber of the first substrate processing tool and then transferred through a vacuum transfer module to the first processing chamber of the first substrate processing tool.

19. The method of claim 1, wherein the polymer film includes a polymer backbone with alternating carbon-oxygen bonds.

20. The method of claim 1, wherein the polymer film comprises polyoxymethylene, polyacetaldehyde, polypropionaldehyde, polybutyraldehyde, polyvaleraldehyde, polyheptaldehyde, polyoctanaldehyde, polynonanaldehyde, polydecaldehyde, or any combination thereof.

21. The method of claim 1, wherein the polymer film is a copolymer comprising a homopolymer selected from a group consisting of polyoxymethylene, polyacetaldehyde, polypropionaldehyde, polybutyraldehyde, polyvaleraldehyde, polyheptaldehyde, polyoctanaldehyde, polynonanaldehyde, and polydecaldehyde.

22. The method of claim 1, further comprising, during deposition of the of the polymer film, delivering precursor selected from a group consisting of monomeric aldehyde and a precursor with alternating carbon-oxygen ring structures.

23. The method of claim 22, wherein the precursor is selected from a group consisting of 1,3,5-trioxane and paraldehyde.

24. The method of claim 22 or 23, wherein the monomeric aldehyde is selected from a group consisting of formaldehyde, ethanal, propanal, butanal, pentanal, hexanal, heptanal, octananal, nonanal, or decanal, or any non-linear branched version of these molecules.

25. The method of claim 1, wherein the polymer film has a thickness in a range from 10 nm to 5000 nm.

26. The method of claim 1, wherein the polymer film has a thickness in a range from 100 nm to 1000 nm.

27. The method of claim 1, further comprising performing post processing on the polymer film.

28. The method of claim 27, wherein the post processing is selected from a group consisting of exposure to solvent, annealing and a soft bake.

29. The method of claim 1, wherein removing the polymer film comprises exposing the polymer film to radiation.

30. The method of claim 1, further comprising controlling a temperature of a substrate support during deposition of the polymer film to a temperature that is less than other surfaces in a processing chamber where the deposition of the polymer film occurs.

31. The method of claim 1, further comprising depositing a cap layer on the polymer film.

32. The method of claim 31, wherein the cap layer is deposited by a CVD process in the first substrate processing tool.

33. The method of claim 31 or 32, wherein the cap layer is an inorganic layer.

34. The method of claim 31 or 32, wherein the cap layer comprises one or more of: SiOₓ, SnOₓ, AlOₓ, TiOₓ, ZrOₓ, HfOₓ, ZnOₓ, and SiNₓ wherein x is a number greater than 0.

35. The method of claim 31 or 32, wherein the cap layer comprises a polymer layer.

36. The method of claim 1, further comprising incorporating an organic weak acid in the polymer film.

37. A method comprising:
performing a first substrate treatment on a substrate using a first dry process in a first substrate processing tool operating at vacuum;
after the first substrate treatment, depositing a polymer film comprising a polymer on an exposed surface of the substrate using a chemical vapor deposition (CVD) process in the first substrate processing tool;
removing the substrate from the first substrate processing tool for a queue period,
wherein the polymer is selected from a group consisting of polyacetaldehyde, polypropionaldehyde, polybutyraldehyde, polyvaleraldehyde, polyheptaldehyde polyoctanaldehyde, polynonanaldehyde, and polydecaldehyde.

38. The method of claim 37, further comprising depositing a cap layer on the polymer film.

39. The method of claim 38, wherein the cap layer is deposited by a CVD process in the first substrate processing tool.

40. The method of claim 38 or 39, wherein the cap layer is an inorganic layer.

41. The method of claim 38 or 39, wherein the cap layer comprises one or more of: SiOₓ, SnOₓ, AlOₓ, TiOₓ, ZrOₓ, HfOₓ, ZnOₓ, and SiNₓ wherein x is a number greater than 0.

42. The method of claim 38 or 39, wherein the cap layer comprises a polymer.

43. The method of claim 37, further comprising incorporating an organic weak acid in the polymer film.

44. A method comprising:
performing a first substrate treatment on a substrate using a first dry process in a first substrate processing tool operating at vacuum;
after the first substrate treatment, depositing a polymer film comprising a polymer on an exposed surface of the substrate using a chemical vapor deposition (CVD) process in the first substrate processing tool;
removing the substrate from the first substrate processing tool for a queue period,
wherein the polymer is a copolymer comprising a homopolymer selected from a group consisting of polyoxymethylene, polyacetaldehyde, polypropionaldehyde, polybutyraldehyde, polyvaleraldehyde, polyheptaldehyde, polyoctanaldehyde, polynonanaldehyde, and polydecaldehyde.

45. The method of claim 44, further comprising depositing a cap layer on the polymer film.

46. The method of claim 45, wherein the cap layer is deposited by a CVD process in the first substrate processing tool.

47. The method of claim 45 or 46, wherein the cap layer is an inorganic layer.

48. The method of claim 46 or 47, wherein the cap layer comprises one or more of: SiOₓ, SnOₓ, AlOₓ, TiOₓ, ZrOₓ, HfOₓ, ZnOₓ, and SiNₓ wherein x is a number greater than 0.

49. The method of claim 45, wherein the cap layer comprises a polymer.

50. The method of claim 44, further comprising incorporating an organic weak acid in the polymer film.
